(19) United States
(12) Patent Application Publication
(10) Pub. No.: US 2006/0261424 A1
(43) Pub. Date: Nov. 23, 2006

(54) Integrated pressure and acceleration measurement device and a method of manufacture thereof

(75) Inventor: Appolonius Jacobus A. Van Der Wiel, Tervuren (BE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Melexis NV, Ieper (BE)

(21) Appl. No.: 10/544,038

(22) PCT Filed: Feb. 2, 2004
(86) PCT No.: PCT/IB04/00246

§ 371 Date: Jul. 12, 2006

(30) Foreign Application Priority Data
Jan. 31, 2003 (GB) 0302271.2

(51) Int. Cl. H01L 29/84

(52) U.S. Cl. 257/417

(57) ABSTRACT

An integrated pressure and acceleration sensing device comprises three silicon wafers (101-103) bonded together by silicon fusion bonding. The wafers (101-103) are shaped so as to define a pressure sensitive element (113) and an acceleration sensing element (112). At least one stress measuring means linked to each of said pressure sensing and acceleration sensing elements (113,112) which are operable to generate a measurement signal responsive to deformation of said stress measuring means and which is indicative of the sensed values of pressure and/or acceleration. The device is manufactured by shaping said silicon wafers (101-103) define parts which act to form pressure and acceleration sensing elements (113,112) and bonding said silicon wafers (101-103) together using bonding techniques such as silicon fusion bonding, anodic bonding or glass-frit bonding. The wafers (101-103) are polished or lapped said to produce a relatively thin single integrated device.

The present invention relates to an integrated pressure and acceleration measurement device and a method of manufacture thereof.

Tyre Pressure Monitoring Systems (TPMS) are commonly used as a safety device in cars or other vehicles in order to allow a warning to be provided to the driver when the tyre pressure is not within acceptable limits These systems are typically disposed within the car tyre and usually include a pressure sensing element, a temperature sensing element, a signal processor and an RF transmitter. Electrical power for the system is provided by a suitable power source, for example a battery.

In order to allow a sufficient lifetime of the battery (usually to 10 years or more) the system is usually arranged such that, as the transmitter typically consumes the most power, transmission of signals is restricted to periods when the car is moving. During these periods the system transmits regularly to allow a receiver to confirm that the system is operating correctly. Should the receiver fail to receive an appropriate signal from the system whilst the vehicle is in motion, an indication will be provided to the driver to alert him that there is a problem with the system.

It will be appreciated that the system must be able therefore to distinguish between periods when the car is moving and periods when the car is not in use. Since the system is usually a stand-alone device, it has to sense the period when the car is moving by detecting movement of the car itself. To achieve this, normally such systems incorporate a motion-sensing device to detect movement of the car.

Most motion sensing devices used in systems of this kind are based on an acceleration switch. In such switches an electrical contact is established when an acceleration force acts on a mass connected to the switch. Allowing movement of the car to be detected. Problems arise with such switches since these are typically assembled out of several parts and are therefore relatively large as compared to other components forming the system. Additionally, being a mechanical switch in which parts regularly contact each other, such switches are prone to wear of the contacting surfaces which can lead to sharp electrical surface changes resulting in an enhancement of corrosion of the surfaces and contributing to early failure of the switch.

It has been realised that it is advantageous to use small and light components for systems of this kind since they are exposed to large centrifugal accelerations up to 1500 g.

Therefore it has been proposed to use a silicon motion detector in these systems since this can be made in very small sizes and is more reliable. When made in this way, a piezoresistor can be used to detect movement by a change in resistance when an acceleration force is present. Such electronic acceleration sensors have been used previously in Air bag collision and roll over sensing devices and have proved their performance and reliability in the automotive environment.

In order to form a Tyre Pressure Monitoring system it has been realised that if it is possible to build the pressure sensing device and the motion-detecting device with the same basic fabrication process, the pressure sensing device and the motion-detecting device can be integrated on the same integrated circuit device. This can not only allow the fabrication of smaller devices with reduced fewer interconnections and can also reduce assembly costs. In addition, miniaturisation of TPMS systems also improves the quality of these systems by reducing strain in the systems when they are exposed to the very high acceleration forces.

Integrated circuit devices having a combined pressure sensing device and motion detecting device are known (for example such a device is manufactured by Sensonor). These known devices are constructed from 3 wafers, a silicon wafer in the middle and a glass wafer at the top and the bottom. The glass wafers are attached to the silicon wafer by anodic bonding. Normally glass wafers are used to enable anodic bonding of the wafers at temperatures below 400° C. The bonding temperature cannot exceed this temperature, as otherwise the metallization on the silicon wafer would be damaged.

However problems have arisen with devices formed in this way.

Firstly, glass has a much larger thermal expansion coefficient than silicon. This mismatch of thermal expansion induces severe stress in the sensors over the wide temperature range they are used, typically from −40 to 125° C. This mechanical stress can introduce a variable offset error in the output signals generated from a piezoresistor as a function of temperature. This thermal offset can easily exceed the functional span of the sensor.

Secondly, glass is also more difficult to work and structure than is silicon.

Chemical Etching of glass using Potassium Hydroxide (KOH) and grinding of glass is possible but can be very difficult and does not lend itself to a production process. Furthermore, cavities formed in glass wafers tend to be shallow and back-grinding of glass wafers is not thought appropriate to production on an industrial scale. Also in such devices access to the inner silicon wafer to apply a pressure to the pressure sensor, is normally achieved by providing holes in the glass wafer before bonding. Also the dicing of the glass is much more time consuming than dicing of silicon. As a result, the devices made by the combination of 2 glass wafers and one silicon wafer cannot easily be ground down or etched and therefore such devices have a thickness which is much larger than that of conventional integrated circuit devices and, as a consequence, standard integrated circuit packaging such as the SO package family cannot be utilised.

Still further, to expose the electrical bond pads on the middle silicon wafer, and thus permit the electrical connections to be made to the circuit elements on the silicon wafer, areas of the top glass wafer must be removed. Typically the top glass wafer is formed with a (shallow) cavity located above the contact pads. By dicing the glass in line with the device edge and again in line with the inner edge of the contact pads, the glass above the contact pads can be detached from the top cap. Using this method, the glass can only be removed in rectangular shapes, which extend across the entire width of the device.

The sealing quality of the anodic bonding between glass and silicon is sufficient for the use of the device as an accelerometer, since the internal pressure of the acceleration-sensing device only affects the damping of the device and not the sensitivity. Changes of several 100 mbar over the lifetime of the device can normally be tolerated. However, the pressure in the cavity of the pressure-sensing device serves as a reference source and should not change over time. A typical maximum change in value of 30 mbar over 10 years can be accommodated.

Furthermore, devices with glass caps need special attention when they are over moulded in standard high volume packaging processes. During the moulding the devices are exposed to pressures of at least 50 bar at temperatures of about 175° C.

It is accordingly an object of the present invention to provide an integrated pressure sensing device and acceleration sensing device, which minimises or obviates the abovementioned problems associated with existing such devices and a method of manufacturing such a device.

Thus and in accordance with a first aspect of the present invention there is provided method of forming an integrated pressure and acceleration sensing device comprising a silicon-silicon-silicon assembly, said method comprising shaping said silicon wafers by etching such that said shaped wafers define parts which act to form pressure and acceleration sensing elements, bonding said silicon wafers together and polishing or lapping said bonded wafers to produce a relatively thin single integrated device.

Thus and in accordance with a second aspect of the present invention there is provided an integrated pressure and acceleration sensing device comprising three silicon wafers bonded together, said wafers being shaped so as to define a pressure sensitive element and an acceleration sensing element, at least one stress measuring means linked to each of said pressure sensing and acceleration sensing elements which are operable to generate a measurement signal responsive to deformation of said stress measuring means and which is indicative of the sensed values of pressure and/or acceleration.

As silicon caps are much stronger and the thermal internal stress is a lot less for all-silicon devices, silicon caps can be made much thinner than glass caps.

Standard grinding techniques can be used for silicon and the silicon bottom wafer can be made much thinner than a glass one. The bonding between the wafers may be achieved by any suitable bonding method such as silicon fusion bonding, anodic bonding or glass frit bonding.

Preferably, said wafers form a three layer sandwich, said sandwich having top, centre and bottom wafers. The top wafer and the centre wafer may be bonded together by the same method as the bottom wafer and the centre wafer or alternatively, the top wafer and the centre wafer may be bonded together by different method to the bottom wafer and the centre wafer. Preferably, at least the bottom wafer and the centre are bonded together by silicon fusion bonding. The much stronger fusion bond obtained by silicon fusion bonding coupled with the gas diffusion rate through silicon being 2 orders of magnitude smaller than that of glass reduces the variability with time and temperature of the pressure in the pressure sensor reference cavity.

Preferably, the centre wafer has a mass formed integrally therewith which forms the acceleration sensing element and a membrane formed integrally therewith which forms the pressure sensing element. Preferably, the centre wafer carries additional circuitry for control and or operation and or configuration of the integrated device.

Preferably, said top and bottom wafers form matching halves whereby when the matching halves are brought together they define cavities in which the sensing elements are housed. Most preferably, either the top wafer or the bottom wafer is shaped to provide a recess or opening through which the pressure sensing element can be exposed to ambient air pressure. It is also preferable that the top wafer and or the bottom wafer are shaped to provide a recess or opening, thereby defining an area where electrical connections can be made to the circuitry on the centre wafer.

In one preferred embodiment, the mass forming the acceleration sensing element has a relatively thin section and a relatively thick section. Preferably in such embodiments the stress measuring means linked to the acceleration sensing element are provided on the relatively thin section of the acceleration sensing element. Most preferably in the above and alternative embodiments, the stress measuring means comprise piezoresistors.

In another preferred embodiment, two shallow recesses are provided on said bottom wafer facing said centre wafer and one shallow recess and one deep recess are provided on said top wafer facing said centre wafer, one said recess on the bottom wafer in combination with the deep recess on the top wafer member defining a cavity to house the pressure sensing element and the other said recess on the bottom wafer in combination with the shallow recess on the top member defining a cavity to house said acceleration sensing element.

In an alternative preferred embodiment, two shallow recesses are provided on said centre wafer facing said bottom wafer and one shallow recess and one deep recess are provided on said top wafer facing said centre wafer, one said recess on the centre wafer in combination with the deep recess on the top wafer member defining a cavity to house the pressure sensing element and the other said recess on the centre wafer in combination with the shallow recess on the top member defining a cavity to house said acceleration sensing element.

Preferably, in the two above embodiments, the deep recess in the top member is processed to provide an opening through which the pressure sensing element can be exposed to ambient air pressure.

In a further preferred embodiment, the top wafer is a structured silicon top wafer and bonded to the centre wafer by a bonding technique such as anodic bonding or glass-frit bonding to produce a silicon cap which resists standard moulding during packaging. Preferably, the top cap is thinned and filled with thin gel to provide a low g sensitivity pressure sensing element.

Preferably, the total thickness of the device is less than 500 microns.

The wafers may be shaped using wet etching with chemicals such as Potassium Hydroxide (KOH) etching or plasma etching. The wafers may alternatively be bonded together using silicon fusion bonding, glass-frit bonding or anodic bonding. Preferably, the device is thinned by back-grinding one or more wafers. If desired, etching may be used to thin areas of the wafers forming said pressure and acceleration sensing elements.

Holes or openings in the top and bottom wafers may be made by etching or by the combination of etching a recess facing the centre wafer before bonding and grinding or etching from the other surface after bonding.

The invention will now be described further by way of example only and with reference to the accompanying drawings, in which:

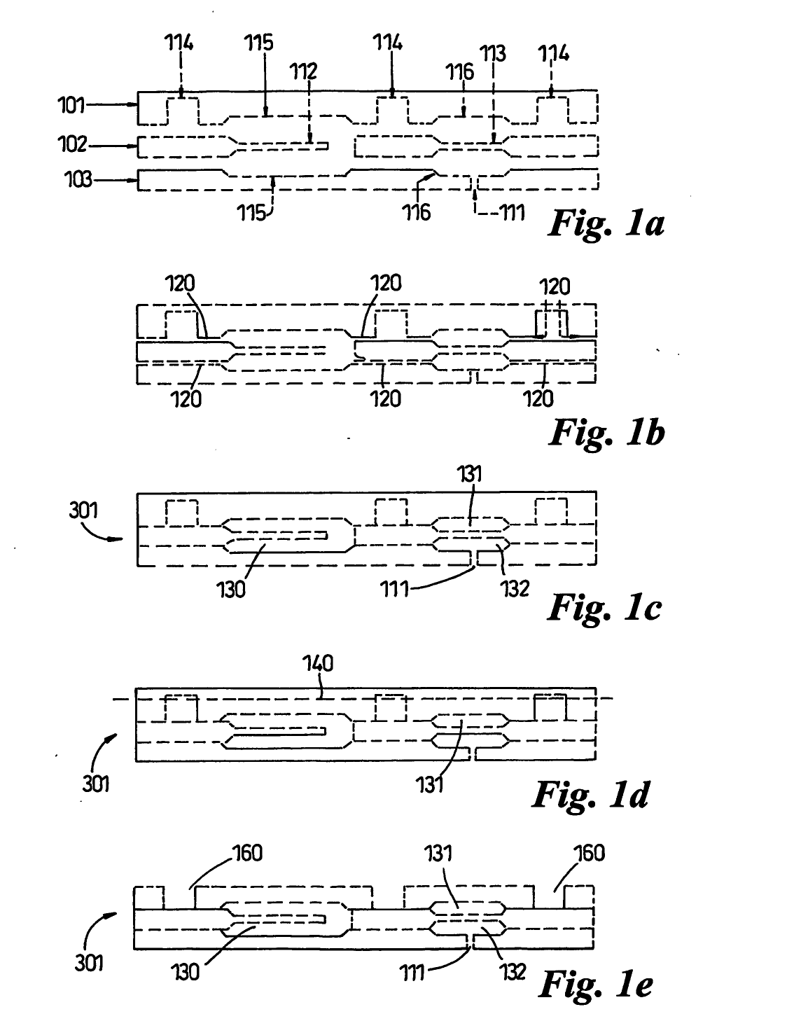

FIGS. 1 a) to e) show the process stages for the manufacture of one embodiment of device in accordance with the present invention;

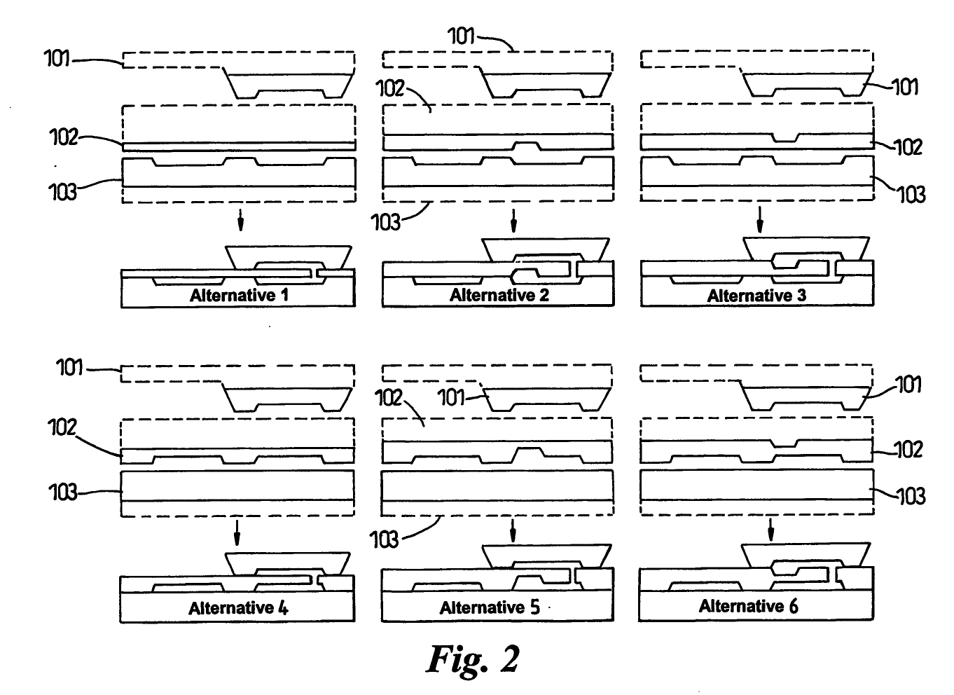

FIG. 2 shows six alternative embodiments of devices in accordance with the present invention; and

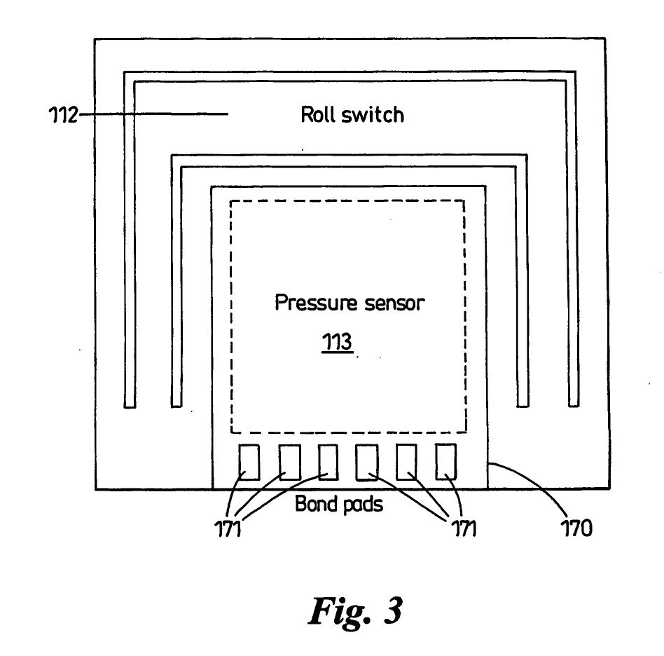

FIG. 3 shows a plan view of one embodiment of device of the present invention formed in accordance of the method of FIGS. 1a) to e) or FIG. 2.

Referring now to the figures there is shown in FIGS. 1a)-e) in cross section the sequence of process stages in the formation of one embodiment of integrated circuit device for monitoring tyre pressure in accordance with the present invention.

The device is formed from a three-layer sandwich of silicon wafers, 101,102,103. The centre wafer, 102, has a mass formed integrally therewith, 112, which forms the motion detecting sensor, and also a membrane 113, which forms the pressure detecting sensor. Wafer 102 also carries strain dependent elements of suitable form and which are required for detecting the deformation of the membrane, 113, and the mass, 112. Wafer 102 may also carry additional circuitry as desired or as appropriate and which may control operation and configuration of the integrated device in its application. The top and bottom wafers, 101,103, are shaped, 115, 116, to form matching halves whereby when the matching halves are brought together, they define cavities in which the sensing elements 112, 113, will be housed. Wafer 103 is further shaped to form an opening 111, through which ambient air pressure can be applied to one side of the pressure sensing membrane, 113. The top wafer, 101, is further shaped to define a relatively deep recess, 114, which defines an area where electrical connections can be made to the circuitry on wafer 102.

The shaping of the wafers is typically carried out using Potassium Hydroxide (KOH) etching or plasma etching and is fully compatible with conventional silicon processing.

The three shaped wafers are assembled together to form an integrated device 301, using silicon fusion bonding techniques at the mating surfaces 120. The device assembly, 301, contains a sealed cavity 130 within which is the acceleration sensing element, a sealed cavity 131, which acts as the reference pressure for the pressure sensing element and cavity 132, exposed to ambient pressure via opening 111.

The device assembly is then lapped on its top surface to a line 140, which removes all the silicon in those areas, 160, where electrical connection is to be made to circuitry on wafer 102.

All three silicon wafers have the same thermal coefficient of expansion to avoid mismatch of thermal expansion. This reduces thermal offset drift to a minimum.

FIG. 2 shows a number of alternatively shaped arrangements of devices, which are further embodiments of the invention. In all of these arrangements lapping is used to control the end thickness of each of the three wafers.

In alternative 1 the middle wafer is bonded to the lower wafer and then lapped down to the desired thickness to form the membrane and the mass. The mass is etched free from the wafer to from a cantilever arrangement.

In alternative 2 the mass area on the middle wafer 103 is pre shaped before bonding to the lower wafer. This gives a thin section for the flexible part of the cantilever arrangement but a thicker section for the pressure sensor.

Alternative 3 is similar to alternative 2 but the shaping of the cantilevered mass is done after the silicon fusion bonding stage.

Alternatives 4, 5 and 6 show similar process steps to alternatives 1, 2 and 3 but with cavities shaped into the middle wafer and not the lower wafer.

In these alternatives the membrane is exposed directly to the ambient pressure and not through an orifice in a cavity. Bonding the middle wafer 103 to the bottom wafer 103 forms the final cavities. The final thickness of the membranes for both the pressure sensing device and the acceleration sensing device are obtained by back-grinding and polishing of the middle wafer after bonding this wafer to the bottom one.

Silicon etching can also be used to make certain well-defined areas in the membrane thinner. This can be used to increase the sensitivity of the acceleration-sensing device by thinning the areas containing the piezoresistors of the cantilever. Thinning certain areas of the membrane for the pressure-sensing device can also be used to improve the linearity of this device. This second etch can be executed before the bonding, back-grinding and polishing of the membrane (Alternative 2 and 5) or afterwards (Alternative 3 and 6).

The electrical elements such as bond-pads, piezoresistors and ESD structures are typically formed after the back-grinding and polishing of the membranes, but before placing the top wafer.

The top wafer is shaped in such a way that by placing it on the middle wafer a deep recess is facing the pressure sensing area and the bond pads, whereas a shallow recess is facing the area with the cantilever arrangement for acceleration sensing. The top wafer can be bonded to the middle wafer using anodic bonding. Due to the different depths of the recesses, back-grinding the top wafer opens the areas above the pressure sensing area and the bond pads and leaves the cavities of the acceleration device sealed.

The structure does not need special wafer sawing as the opening of the bond-pads and the pressure sensing area is obtained by back-grinding. Due to this back-grinding a relatively thin device is obtained. In contrast to the dicing method, the thinning method is not limited to rectangular shapes for the top cover, as the etching of the silicon determines the shape of the recesses. This has as a consequence that the acceleration sensing part of the device does not have to be rectangular, whereas the method with dicing always results in rectangular shapes. Due to the back-grinding process, sensors can be formed with new layouts of which one example is depicted in FIG. 3, which shows an opened square area 170 in the area of the midpoint of the silicon wafers. Such an area cannot be cut with a saw. The opened square area 170 contains the pressure sensing membrane 112 and bond pads 171 for facilitating connection to external circuitry. The raised area around said opened area 170 covers the mass 112 comprising the acceleration sensing element.

The total thickness of the integrated device can be further reduced by back-grinding of the bottom wafer. Hence a 3-layer structure can be obtained with a total thickness of less than 200 microns. However, thinning of the bottom wafer may deteriorate the offset behaviour of the device.

The device of the invention demonstrates a number of advantages over the prior art.

Thus, for example, two sensors are provided in one integrated device which reduces the number of bond wires, allows the use of normal electronic packaging for a Total System in Package strategy, reduces the foot print of the sensors in the package and improves reliability

An all silicon solution using Silicon Fusion Bonding produces sealed cavities with guaranteed long-term stability of the reference pressure and also allows area optimisation for the sensing devices by not etching through the wafer and gives small offsets due to matching thermal expansion.

Such a small offset variation can enable electronic circuitry to be configured to correlate offset with cavity pressure and to monitor the quality of the cavity pressure by examination of the offset

Using a structured silicon top wafer and anodic bonding produces a silicon cap, which resists standard moulding during packaging. Back-grinding of the silicon cap allows freedom to optimise contact openings reduce the area and to allow a better bond pad layout. Thinning all 3 wafers enable a device to be packaged in standard SO package.

A thinned cap allows thin gel filling for low g sensitivity of the pressure sensor.

It is of course to be understood that the invention is not intended to be restricted to the details of the above embodiments, which are described by way of example only.

1. An integrated pressure and acceleration sensing device comprising three silicon wafers bonded together by silicon fusion bonding, said wafers being shaped so as to define a pressure sensitive element and an acceleration sensing element, at least one stress measuring means linked to each of said pressure sensing and acceleration sensing elements which are operable to generate a measurement signal responsive to deformation of said stress measuring means and which is indicative of the sensed values of pressure and/or acceleration.

2. An integrated pressure and acceleration sensing device as claimed in claim 1 wherein said wafers form a three layer sandwich, said sandwich having top, centre and bottom wafers.

3. An integrated pressure and acceleration sensing device as claimed in claim 2 wherein the centre wafer has a mass formed integrally therewith which forms the acceleration sensing element.

4. An integrated pressure and acceleration sensing device as claimed in claim 2 wherein the centre wafer has a membrane formed integrally therewith which forms the pressure sensing element.

5. An integrated pressure and acceleration sensing device as claimed in claim 2 wherein the centre wafer carries additional circuitry for control and or operation and or configuration of the integrated device.

6. An integrated pressure and acceleration sensing device as claimed in any one of claim 2 wherein said top and bottom wafers form matching halves whereby when the matching halves are brought together they define cavities in which the sensing elements are housed.

7. An integrated pressure and acceleration sensing device as claimed in claim 6 wherein either the top wafer or the bottom wafer is shaped to provide an opening through which the pressure sensing element can be exposed to ambient air pressure.

8. An integrated pressure and acceleration sensing device as claimed in claim 6 wherein the top wafer and or the bottom wafer are shaped to provide a recess, thereby defining an area where electrical connections can be made to the circuitry on the centre wafer.

9. An integrated pressure and acceleration sensing device as claimed in claim 2 wherein the mass forming the acceleration sensing element has a relatively thin section and a relatively thick section.

10. An integrated pressure and acceleration sensing device as claimed in claim 9 wherein the stress measuring means linked to the acceleration sensing element are provided on the relatively thin section of the acceleration sensing element.

11. An integrated pressure and acceleration sensing device as claimed in claim 1 wherein the stress measuring means comprise piezoresistors.

12. An integrated pressure and acceleration sensing device as claimed in claim 2, wherein two shallow recesses are provided on said bottom wafer facing said centre wafer and one shallow recess and one deep recess are provided on said top wafer facing said centre wafer, one said recess on the bottom wafer in combination with the deep recess on the top wafer member defining a cavity to house the pressure sensing element and the other said recess on the bottom wafer in combination with the shallow recess on the top member defining a cavity to house said acceleration sensing element.

13. An integrated pressure and acceleration sensing device as claimed in claim 2 two shallow recesses are provided on said centre wafer facing said bottom wafer and one shallow recess and one deep recess are provided on said top wafer facing said centre wafer, one said recess on the centre wafer in combination with the deep recess on the top wafer member defining a cavity to house the pressure sensing element and the other said recess on the centre wafer in combination with the shallow recess on the top member defining a cavity to house said acceleration sensing element.

14. An integrated pressure and acceleration sensing device as claimed in claim 12 wherein the deep recess in the top member is processed to provide an opening through which the pressure sensing element can be exposed to ambient air pressure.

15. An integrated pressure and acceleration sensing device as claimed in claim 2 wherein the top wafer is a structured silicon top wafer and bonded to the centre wafer by anodic bonding to produce a silicon cap which resists standard moulding during packaging.

16. An integrated pressure and acceleration sensing device as claimed in claim 15 wherein the top cap is thinned and filled with thin gel to provide a low g sensitivity pressure sensing element.

17. An integrated pressure and acceleration sensing device as claimed in claim 1 wherein the total thickness of the device is less than 200 microns.

18. A method of forming an integrated pressure and acceleration sensing device comprising a silicon-silicon-silicon assembly, said method comprising shaping said silicon wafers by etching such that said shaped wafers define parts which act to form pressure and acceleration sensing elements, bonding said silicon wafers together using silicon fusion bonding, and polishing or lapping said bonded wafers to produce a relatively thin single integrated device.

19. A method of forming an integrated pressure and acceleration sensing device as claimed in claim 18 wherein said wafers are shaped using Potassium Hydroxide (KOH) etching.

20. A method of forming an integrated pressure and acceleration sensing device as claimed in claim 18 wherein said wafers are shaped using plasma etching.

21. A method of forming an integrated pressure and acceleration sensing device as claimed in claim 18 wherein one or more of the wafers are bonded together using anodic bonding.

22. A method of forming an integrated pressure and acceleration sensing device as claimed in claim 18 wherein the device is thinned by back-grinding one or more wafers.

23. A method of forming an integrated pressure and acceleration sensing device as claimed in claim 18 wherein etching is used to thin areas of the wafers forming said pressure and acceleration sensing elements.

24. An integrated pressure and acceleration sensing device as claimed in claim 1 wherein the device is made by the method of claim 18.

25. An integrated pressure and acceleration sensing device as claimed in claim 13 wherein the deep recess in the top member is processed to provide an opening through which the pressure sensing element can be exposed to ambient air pressure.
